(19) United States
(12) Patent Application Publication
(10) Pub. No.: US 2025/0243603 A1
(43) Pub. Date: Jul. 31, 2025

(54) CVD SINGLE CRYSTAL DIAMOND

(71) Applicant: Element Six Technologies Limited, Didcot, Oxfordshire (GB)

(72) Inventors: Benjamin Simon TRUSCOTT, Didcot, Oxfordshire (GB); Stephanie LIGGINS, Didcot, Oxfordshire (GB); Andrew Mark EDMONDS, Didcot, Oxfordshire (GB); Douglas John GEEKIE, Didcot, Oxfordshire (GB); William Joseph HILLMAN, Didcot, Oxfordshire (GB)

(21) Appl. No.: 18/702,089

(22) PCT Filed: Oct. 19, 2022
(86) PCT No.: PCT/EP2022/079140

§ 371 Date: Apr. 17, 2024

(30) Foreign Application Priority Data
Oct. 19, 2021 (GB) 2114934.9

(51) Int. Cl. C30B 29/04; C09K 11/65; C30B 25/20; C30B 33/02; C30B 33/04

(52) U.S. Cl. CPC C30B 29/04; C09K 11/65; C30B 25/20; C30B 33/02; C30B 33/04

(57) ABSTRACT

A CVD single crystal diamond having a concentration of single substitutional nitrogen atoms, Nₛ⁰, in their neutral charge state as measured by EPR of between 0.25 and 3 ppm, and wherein the CVD single crystal diamond has a total concentration of nitrogen vacancy centres in their neutral and negative charge states (NV⁰ and NV⁻) that is between 0.1 and 0.8 times the Nₛ⁰ concentration.

### FIELD OF THE INVENTION

This invention relates to CVD single crystal diamond, and methods of making CVD single crystal diamond.

### BACKGROUND

In the 1980s and 1990s much research was performed by various groups around the world directed to the synthesis of single crystal CVD diamond material. Much of this work disclosed growth of thin layers of single crystal CVD diamond material on single crystal diamond substrates via homoepitaxial growth. While there was a desire to fabricate relatively thick layers of high quality single crystal CVD synthetic diamond material, this proved difficult to achieve in practice. Synthesis of single crystal CVD diamond material requires extreme conditions which need to be generated and then maintained in a stable fashion over extended time periods to successfully grow thick layers of high quality single crystal CVD synthetic diamond material. Furthermore, the nature of the diamond material which is synthesized is sensitive to numerous synthesis parameters forming a complex multi-dimensional synthesis parameter space. Only small areas of this multi-dimensional synthesis parameter space are capable of achieving thick layers of high quality single crystal CVD diamond material. Finding these synthesis regimes, and developing methodologies for generating the correct combination of parameters required to produce and maintain stable growth within one of these synthesis regimes is far from trivial.

Synthesis parameters of importance to single crystal CVD diamond growth include substrate type (for example, whether it be produced by CVD, high-pressure/high-temperature, or natural geological synthesis), the method of substrate preparation from the original host crystal, substrate geometry (including crystallographic orientation of the faces and/or edges), substrate temperature during growth and thermal management of growing crystals, and the gas-phase synthesis environment itself. The latter is influenced by the process gas composition (including impurities), gas pressure within the process chamber, and amount of microwave power supplied for the synthesis process, in addition to various hardware-dependent factors such as the size of the process chamber, process gas inlet/outlet geometry, and process gas flow rate. Many of these parameters are interrelated such that if one parameter is changed then others must also be changed in the correct manner in order to remain in an appropriate growth regime. Failure to select and maintain suitable process conditions over the full deposition area for the entire duration of the synthesis process can result in a high level of uncontrolled process variability, unusable product with inappropriate material properties, or even complete destruction of the crystals by catastrophic cracking, twinning, or graphitization.

It is known to deliberately add defects in the form of dopants. Nitrogen is one of the most important dopants in CVD diamond material synthesis, as it has been found that providing nitrogen in the CVD process gas increases the growth rate of the material and can also affect the formation of crystallographic defects such as dislocations. As such, nitrogen doping of single crystal CVD synthetic diamond materials has been extensively investigated and reported in the literature. For some applications, such as electronic applications, it has been found to be advantageous to develop techniques which intentionally exclude nitrogen from the CVD process gases. However, for other applications, nitrogen doping to significant levels can convey advantageous properties and/or be useful in achieving growth of thick layers of CVD synthetic diamond material. Patent literature relevant to such nitrogen doped single crystal CVD synthetic diamond material includes WO2003/052177.

Intrinsic diamond material has an indirect band gap of 5.5 eV and is transparent in the visible part of the spectrum. Introducing defects, or colour centres, which have associated energy levels within the band gap gives the diamond a characteristic colour that is dependent on the type and concentration of the colour centres. This colour can result from either absorption or photoluminescence or some combination of these two. Generally, absorption is the dominant factor. One example of a common colour centre present in synthetic diamond material is nitrogen which, when on a substitutional lattice site in the neutral charge state, has an associated energy level 1.7 eV below the conduction band which causes absorption at the blue end of the visible spectrum, which by itself causes the diamond to have a characteristic yellow colour. Such a nitrogen atom when on a substitutional lattice site in the neutral charge state is known as a Nₛ⁰ defect, the concentration of which is denoted by [Nₛ⁰].

It is known, for example from WO2010/149775, that irradiating and annealing of CVD diamond material containing single substitutional nitrogen, Nₛ⁰, can give rise to pink coloured diamond The term “fancy-coloured diamond” is a well-established gem trade classification and is used to refer to unusually coloured diamonds.

Examples of fancy coloured synthetic and natural diamonds made by introducing colour centres into the diamond are known in the prior art. For example, EP0615954A and EP0316856A describe irradiation of synthetic diamond material with an electron beam or a neutron beam to form lattice defects (interstitials and vacancies) in the crystal. Thereafter the diamond crystal is annealed in a prescribed temperature range to form colour centres. One colour centre described is a substitutional nitrogen atom adjacent to a vacancy, referred to as an “NV centre”, which can give the diamond material a desirable fancy colour, such as purple (as described in EP0316856A) or red/pink (as described in EP0615954A).

NV centres are not just useful for providing a pink colour to diamond, but have many important uses in other fields. NV centres have been investigated for use in various imaging, sensing, and processing applications including: luminescent tags; magnetometers; spin resonance devices such as nuclear magnetic resonance (NMR) and electron spin resonance (ESR) devices; spin resonance imaging devices for magnetic resonance imaging (MRI); quantum information processing devices such as for quantum communication and computing; magnetic communication devices; and gyroscopes for example. The NV centre has attracted interest as a useful quantum spin defect because it has several desirable features including:
(i) Its electron spin states can be coherently manipulated with high fidelity and have an extremely long coherence time (which may be quantified and compared using the transverse relaxation time T2 and/or T2*);
(ii) Its electronic structure allows the defect to be optically pumped into its electronic ground state allowing such defects to be placed into a specific electronic spin state even at non-cryogenic temperatures. This can negate the requirement for expensive and bulky cryogenic cooling apparatus for certain applications where miniaturization is desired. Furthermore, the defect can function as a source of photons which all have the same spin state; and
(iii) Its electronic structure comprises emissive and non-emissive electron spin states, which allows the electron spin state of the defect to be read out through photons. This is convenient for reading out information from synthetic diamond material used in sensing applications such as magnetometry, spin resonance spectroscopy, and imaging. Furthermore, it is a key ingredient towards using NV-defects as qubits for long-distance quantum communications and scalable quantum computation. Such results make the NV-defect a competitive candidate for solid-state quantum information processing (QIP).

A plurality of single crystal CVD synthetic diamonds can be fabricated in a single CVD growth cycle or run (by which is meant a single uninterrupted growth operation in a CVD reactor) by providing a plurality of single crystal diamond substrates on a substrate carrier, introducing process gases, and forming a plasma such that carbon is deposited on the substrates to grow diamond. An issue with this approach to synthesizing a plurality of single crystal CVD diamonds is that of uniformity and yield. Non-uniformities can exist in terms of crystal morphology, growth rate, cracking, and impurity content and distribution. For example, as described in WO2013/087697, even if the CVD diamond growth chemistry is carefully controlled, non-uniform uptake of impurities can still occur due to temperature variations at the growth surface which affect the rate of impurity uptake. Variations in temperature also cause variations in crystal morphology, growth rate, and cracking issues. These temperature variations can be in a lateral direction relative to the growth direction at a particular point in the growth run (spatially distributed) or parallel to the growth direction due to variations in temperature over the duration of a growth run (temporally distributed). Variations can occur within a single CVD diamond crystal and also among crystals when a plurality of them are provided for the synthesis process. As such, in a multi-crystal synthesis process only a portion of product diamond crystals from a single growth run may meet a target specification.

Little prior art exists that speaks both of growing a plurality of CVD single-crystal diamonds and the distribution (consistency or otherwise) of properties resulting among said diamonds. Less still is known on conditions necessary to grow such a plurality of single-crystal diamonds with desirable properties for specific applications at high yield. Considerations relating to uniformity over an area are known in the context of polycrystalline diamond wafers or thin films, but the requirements for growing multiple, relatively large, substantially separate single crystal diamonds bear no relation to what has been disclosed in this respect.

### SUMMARY OF THE INVENTION

It is an object to provide a CVD single crystal diamond synthesis method that allows the production of CVD single crystal diamond in bulk with a uniform concentration of NV centres for a desired application, such as quantum applications or pink gems.

According to a first aspect, there is provided a CVD single crystal diamond having a concentration of single substitutional nitrogen atoms, Nₛ⁰, in their neutral charge state as measured by EPR of between 0.25 and 3 ppm. The CVD single crystal diamond has a total concentration of nitrogen vacancy centres in their neutral and negative charge states (NV⁰ and NV⁻) that is between 0.1 and 0.8 times the Nₛ⁰ concentration.

Optionally, the CVD single crystal diamond has at least one linear dimension no less than 3.5 mm.

As an option, the CVD single crystal diamond has a hue angle, h_{ab}, selected from any of between −45 and 45°, between −10 and 40°, and between 1° and 40°.

The CVD single crystal diamond optionally displays SiV⁻ luminescence, quantitated by the ratio of the total peak area of the SiV⁻ zero-phonon lines to the peak area of the first-order diamond Raman signal in a photoluminescence measurement performed at a temperature of 77 K using an excitation wavelength of 660 nm, selected from any of less than 0.5; less than 0.1; less than 0.05; and less than 0.01. Such values indicate diamond material with very low silicon impurity.

The CVD single crystal diamond optionally has, at a temperature of 20° C., a low optical birefringence, indicative of low strain, such that when measured over an area of at least 3 mm×3 mm the third-quartile value of the difference between the refractive index for light polarised parallel to the slow and the fast axes, averaged over the sample thickness, does not exceed a value selected from any of 1×10⁻⁴, and 5×10⁻⁵. These low birefringence values are indicative of a sample suitable to make single crystal CVD diamond that is free of “graining”, which could otherwise affect its perceived clarity.

As an option, a total volume of the single crystal CVD diamond material is selected from any of at least 0.1 mm², at least 1 mm², at least 10 mm², at least 20 mm², at least 40 mm³, at least 60 mm³, at least 80 mm³ and at least 100 mm³.

The CVD single crystal diamond is optionally in the form of a gem, and having a chroma, C*_{ab}, selected from any of 5 to 40, 10 to 35, and 15 to 30.

Where the resultant diamond is used in applications that take advantage of the spin properties of NV centres, the CVD single crystal diamond optionally has a measured ensemble NV inhomogeneous dephasing time T₂*, as measured by a Ramsey pulse sequence, of greater than 5 μs.

The CVD single crystal diamond is optionally in the form of a gem, and having a colour grade, following the Gemological Institute of America (GIA) scale and methodology, that is selected from any of fancy light, fancy, fancy intense, fancy vivid, and fancy deep, in combination with any of pinkish orange, orangey pink, pink, purplish pink, purple pink and pink purple.

The CVD single crystal diamond is optionally in the form of a gem, and having a clarity grade, following the Gemological Institute of America (GIA) scale and methodology, that is selected from any of VS₂, VS₁, VVS₂, VVS₁, IF, and FL. These clarity grades correspond to samples that either have no clarity defects, or have such defects which however are only observable under magnification and not with the naked eye. Some embodiments of the invention provide single crystal diamond that will typically qualify for one of these grades, allowing gems formed from it to be sold without limitation as either commercial or premium quality goods.

The CVD single crystal diamond optionally further comprises H3, NVN⁰, centres. H3 centres may be formed within the disclosed material when it is heat-treated.

As an option, the CVD single crystal diamond displays a (NV⁰+NV⁻)/H3 ratio of at least 50 in a photoluminescence measurement performed at a temperature of 77 K using an excitation wavelength between 455 and 459 nm, where each of the NV⁰, NV⁻, and H3 defects is quantitated by the peak area ratio of its zero-phonon line to the first-order diamond Raman signal.

The CVD single crystal diamond optionally displays a (NV⁰+NV⁻)/H3 ratio selected from any of at least 100, at least 150, at least 200, at least 300 and at least 400.

According to a second aspect, there is provided a method of making a plurality of single crystal CVD diamonds as described above in the first aspect. The method comprises:
locating a plurality of single crystal diamond substrates on a substrate carrier within a chemical vapour deposition reactor;
feeding process gases into the reactor, the process gases including a hydrogen-containing gas, a carbon-containing gas, and a nitrogen-containing gas, wherein the relative quantities of the process gases are such as to be stoichiometrically equivalent to a C₂H₂/H₂ ratio between 1% and 4%, and a N₂/C₂H₂ ratio between 30 ppm and 300 ppm;
growing the plurality of single crystal CVD diamonds on the surfaces of at least some of the plurality of single crystal diamond substrates at a temperature of between 750° C. and 1000° C.; and
first annealing at least some of the resultant plurality of single crystal CVD diamonds at a temperature of between 1500° C. and 1800° C.;
irradiating the plurality of single crystal CVD diamonds to form vacancies in the diamond crystal lattice; and
second annealing the resultant plurality of single crystal CVD diamonds at a temperature of between 700° C. and 1100° C.

The relative quantities of the process gases are optionally selected so as to be stoichiometrically equivalent to a N₂/C₂H₂ ratio selected from any of between 50 and 200 ppm, between 60 and 180 ppm, and between 70 and 150 ppm.

The relative quantities of the process gases are optionally selected so as to be stoichiometrically equivalent to a C₂H₂/H₂ ratio selected from any of 1 to 3%, 1.5 to 2.5%, and 1.5 to 2%.

As an option, the first annealing is performed at a temperature of between 1550° C. and 1750° C.

As an option, the first annealing is performed under diamond-stabilising pressure. This allows higher temperatures and/or longer annealing times to be used without any loss or damage to the CVD single crystal material by graphitization.

The irradiation is optionally electron irradiation performed with an electron energy between 1 MeV and 10 MeV.

The second annealing optionally comprises annealing in a temperature range selected from any of 700 to 1000° C., 800 to 1000° C., and 850 to 950° C.

As an option, the method further comprises cutting and polishing at least one of the plurality of single crystal diamonds to form a gem.

Optionally, the growth on the substrates is performed without interruption as a single CVD synthesis cycle.

As an option, the step of growing the plurality of single crystal CVD diamonds provides a volumetric growth rate for single-crystal diamond material that is selected from any of at least 10 mm³/h, at least 20 mm³/h, at least 30 mm³/h, at least 40 mm³/h, and at least 50 mm³/h.

The plurality of CVD single crystal diamonds are optionally grown at a temperature selected from any of between 800° C. and 1000° C.; between 800° C. and 950° C.; and between 800° C. and 900° C.

According to a third aspect, there is provided a device comprising the CVD single crystal diamond as described above in the first aspect, the device being selected from any of an imaging device, a sensing device, a magnetometer; a spin resonance device, a quantum information processing device, and a gyroscope device.

### BRIEF DESCRIPTION OF THE DRAWINGS

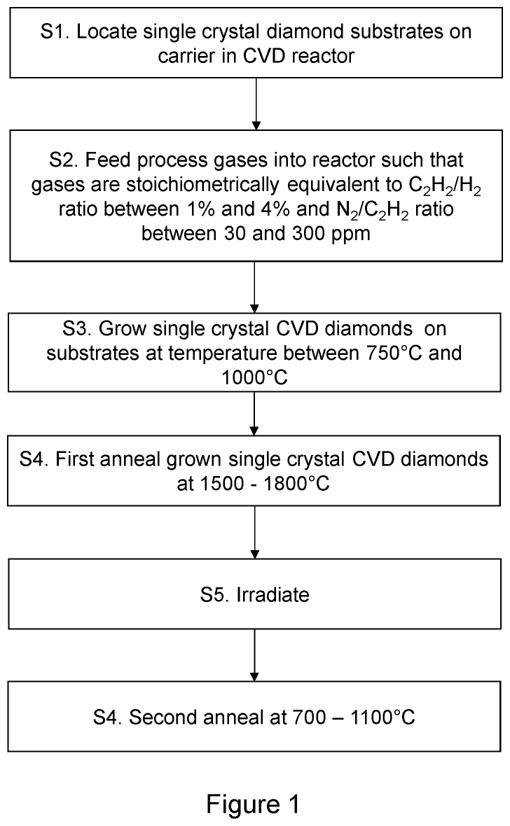

The invention will now be more particularly described, by way of example only, with reference to the accompanying drawing, in which FIG. 1 is a flow diagram showing exemplary steps for making CVD single crystal diamonds.

### DETAILED DESCRIPTION

The present inventors have developed a volume-manufacturable lab grown diamond gem product. The present invention allows the production in a single run of many tens of pieces of single crystal diamond material with predictable properties, such as the concentration of NV centres. For example, the properties may be such that when cut and polished into round brilliant lab grown gems, the diamonds have a high yield with a pink or related GIA colour grading.

The conditions developed by the inventors provide a diamond material with a relatively high growth rate and low internal strain, and so a high yield of diamonds with little cracking is achieved. This in part is due to using substrates with very few surface defects such as etch puts which would otherwise form as nucleation points for bundles of extended defects, which increases strain as described in WO2004/046427. A suitable way to achieve this is to use vertically cut substrates, as described in WO2004/027123, the contents of which are incorporated herein by reference. In this disclosure, a method of producing a plate of single crystal diamond is described, which includes the steps of providing a diamond substrate having a surface substantially free of surface defects, growing diamond homoepitaxially on the surface by chemical vapour deposition (CVD) and severing the homoepitaxial CVD grown diamond and the substrate transverse, typically normal (that is, at or close to 90°), to the surface of the substrate on which diamond growth took place to produce a plate of single crystal CVD diamond. This plate of single crystal diamond is then used as a substrate for further growth. As the extended defects tend to follow the growth direction, slicing the diamond transverse to the growth direction ensures that the new sliced face has a very low concentration of surface defects.

When attempting to grow lab grown gem stones in volume, a further problem is uniformity of the perceived colour of the diamonds. It is desirable to have process conditions that will provide a colour that is perceptibly uniform both within a given gem and among separate gems nominally manufactured to a common specification.

As described above, the presence of nitrogen can lead to a yellow colour. Additionally, CVD single crystal material grown with substantial nitrogen addition typically grows quickly and as a result incorporates vacancy complexes (for example, clusters or chains) which confer a brown hue. This brown colour can be reduced or removed by heat treating the diamond, as described in WO2004/022821, the contents of which are incorporated herein by reference. This document describes heating diamond to temperatures greater than 1400° C. at diamond stabilising pressure. This is known as high-pressure/high-temperature (HPHT) annealing.

In order to form a sufficient number of NV centres, which can give rise to a pink colouration, an irradiation step is typically performed before annealing in order to introduce vacancies into the diamond lattice in excess of the relatively small number typically incorporated during growth. On subsequent annealing, vacancies can migrate towards nitrogen in the diamond crystal lattice to form NV centres.

Nitrogen can be incorporated into a diamond crystal lattice in many different ways. Some of the key ones are as follows:

Single substitutional nitrogen (Nₛ⁰) is when a single nitrogen atom substitutes for a carbon atom in the diamond lattice. It displays an infrared absorption band at 1130 cm⁻¹ (0.140 eV), and typically gives a brown colour.

A negatively charged nitrogen vacancy centre (NV⁻) is a defect where a vacancy and a substitutional nitrogen form a pair in the crystal lattice with an overall negative charge state. NV⁻ displays an absorption line at 637 nm (1.945 eV) and associated bands, and typically provides a pink or purple colour.

An H3 centre consists of two substitutional nitrogen atoms separated by a vacancy in an overall neutral charge state (N-V-N)⁰. H3 displays an absorption line at 503.2 nm (2.463 eV) and associated bands, and gives a yellow colour.

### EXAMPLE

A plurality of single crystal diamond substrates were obtained using plates of CVD single crystal diamond transversely cut, as described in WO2004/027123. These were attached to a carrier and placed in a CVD reactor. Process gases were fed into the CVD reactor. The process gases included hydrogen, a carbon-containing gas (in this example, methane) and a nitrogen-containing gas (here, molecular nitrogen). A plasma of the process gases was formed within the reactor and single crystal CVD diamond material was grown on a surface of each of the plurality of single crystal diamond substrates to a thickness of between 4 and 6 mm.

The resultant single crystal diamonds were then annealed at a pressure of above 6 GPa to ensure they were in the diamond stable region, and at a temperature of between 1550° C. and 1750° C. Prior to annealing, any polycrystalline material was removed, along with surface cracks and defects that would otherwise increase the risk of failure during annealing.

The annealing temperature was maintained between 1550° C. and 1750° C. for a time selected in order to maximize NV retention and avoid H₃ production. This is to maximise the pink colour obtained from the NV centres and ensure that as little yellow from H₃ centres is produced. A temperature of below 1750° C. allows the vacancies to be mobile while the NV centres are less mobile, and so less likely to from H₃ centres.

After the first (HPHT) annealing, the single crystal diamonds were electron-irradiated using an electron energy of between 1 MeV and 10 MeV, and subsequently annealed again, this time at a temperature of between 700 and 1000° C. to form NV centres. Because of the lower temperatures required in the second anneal, it is not necessary to perform it under diamond-stabilizing pressure. In this example, it was performed in a vacuum furnace.

The resultant single crystal diamonds were cut and polished to form round brilliant gems, and had a GIA fancy colour grade of either “fancy intense orangy pink” or “fancy vivid pink” depending on exact synthesis and treatment conditions. Note that the gems can be cut such that they contain the substrate, which reduces the time required to grow the diamond. This is particularly suitable where the substrate is made using the same process as the final diamond, so there is no visible discontinuity.

Quantitative measurements of the colour of a finished gem are difficult because of specularity, multiple internal reflections, and dispersion within the polished article, which produce localized highlights and flashes of apparent colour that depend mostly on the illumination conditions and which need to be discounted to assess the true body colour of the gem. To make such measurements, the photographic approach described in WO2016/203210 was used, which is a faster but still reliable alternative to the use of a spectrophotometer and integrating sphere, and as such particularly useful when many polished gems are to be measured. The measured hue angle for the finished gems lay in the range 25°<h_{ab}<35°, with a majority of the gems tightly clustered around h_{ab}=30°. Chroma values were typically 20<C*_{ab}<30, and a majority of the measured gems fell very close to the middle of the range near C*_{ab}=25. These values were chosen as an example, and it should be noted that both the hue angle and the chroma can be adjusted within the scope of the present invention by suitably varying the synthesis and/or irradiation conditions to change the relative and/or absolute concentrations of Nₛ and NV present in the finished sample. In this way, a variety of aesthetic preferences can be met.

A photoluminescence (PL) measurement was performed for SiV⁻ at 77 K excited using a 660 nm diode laser. Due to the superlative sensitivity of low-temperature PL, a quantifiable SiV signal is nearly always observed in such a measurement on CVD synthetic diamond material, even for samples containing orders of magnitude less SiV than would be detectable in absorption. As with the other PL measurements, the reported value is the area ratio of the SiV⁻ PL feature to the first-order diamond Raman line, except that at low temperature SiV⁻ displays two ZPLs, at 736.5 and 736.8 nm respectively, so that SiV 660=| (736.5 nm)/I(R1₆₆₀)+I(736.8 nm)/I(R1₆₆₀). In these samples, SiV⁻₆₆₀ typically took values between 0.001 and 0.01, which are exceptionally small by the standards of marketed CVD synthetic gems.

Birefringence measurements were made on the CVD single crystal diamond material. Grown diamond material was formed into cubes. The cubes had {110}-oriented side faces with edge lengths equal to the substrate diagonal, so that they circumscribed the area of the original substrate, and {100}-oriented top and bottom faces. The cubes were annealed as described above, and then horizontally cut into plates 0.7 mm thick, with both major faces polished. Birefringence (defined as the difference between the refractive indices for light polarised parallel to the slow and the fast axes, averaged over the sample thickness) was measured for the plates at a wavelength of 590 nm using a commercial instrument (Thorlabs LCC7201), and for most of the area it took values on the order of 10⁻⁵, well within the scope of WO2004/046427, which describes material suitable for optical applications such as etalons. Exceptions were the regions directly above the substrate edges, where dislocations tend to be concentrated at the boundaries between the lateral and vertical growth sectors, and which showed localized maximum birefringence on the order of 10⁻⁴. Although the inclusion of these more-birefringent portions of the crystal might not be preferred in all technical applications, it was found that they are not detrimental to the visual clarity of CVD single crystal diamond given that they occupy only a small fraction of the total volume, and in any case the maximum birefringence is less than 1% that of synthetic moissanite (4.3×10⁻², as quoted in “Synthetic moissanite: a new diamond substitute”, Gems and Gemology volume 33, issue 4, winter 1997).

For applications where the spin state of NV centres in the diamond is utilized, the decoherence time T₂* can be measured. Values for T₂* were determined via a Ramsey pulse sequence, and were found to be greater than 5 μs.

FIG. 1 is a flow diagram illustrating exemplary steps for making CVD single crystal diamonds. The following numbering corresponds to that of FIG. 1:
S1. A plurality of single crystal diamond substrates is located on a substrate carrier within a CVD reactor.
S2. Process gases are fed into the reactor. The process gases include a hydrogen-containing gas, a carbon-containing gas, and a nitrogen-containing gas. The relative quantities of these gases are such as to be stoichiometrically equivalent to a C₂H₂/H₂ ratio between 1% and 4% and a N₂/C₂H₂ ratio between 30 ppm and 300 ppm. Microwaves are used to generate a plasma from the gases. The relative quantities of the process gases may be selected so as to be stoichiometrically equivalent to a N₂/C₂H₂ ratio selected from any of between 50 and 200 ppm, between 60 and 180 ppm, and between 70 and 150 ppm. Furthermore, the relative quantities of the process gases may be selected so as to be stoichiometrically equivalent to a C₂H₂/H₂ ratio selected from any of 1 to 3%, 1.5% to 2.5%, and 1.5 to 2%.
S3. Single crystal CVD diamonds are grown on the surfaces of the plurality of single crystal diamond substrates at a temperature of between 750° C. and 1000° C. The growth is preferably performed as a single continuous and uninterrupted CVD synthesis cycle or “run”. A volumetric growth rate for the cycle may be selected from any of at least 10 mm³/h, at least 20 mm³/h, at least 30 mm³/h, at least 40 mm³/h, and at least 50 mm³/h. The growth temperature is typically of between 800° C. and 1000° C., between 800° C. and 950° C., or between 800° C. and 900° C.
S4. The resultant plurality of single crystal CVD diamonds undergo a first annealing at a temperature of between 1500° C. and 1800° C. At temperatures much above 1800° C., any nitrogen in the crystal can form H3 centres, which means that single substitutional nitrogen is no longer available for subsequent processing to form NV centres. The skilled person may choose to anneal at less than 1750° C. to further reduce the formation of H3 centres. Annealing is preferably performed under diamond-stabilising pressure to reduce the risk of graphitisation.
S5. The plurality of single crystal CVD diamonds are irradiated to form vacancies in the diamond crystal lattice. This may be carried out, for example, using electron irradiation at between 1 and 10 MeV.
S6. A second annealing is carried out on the irradiated single crystal CVD diamonds at a temperature of between 700° C. and 1100° C. to form NV centres. The second annealing may be carried out at a temperature selected from any of 700 to 1000° C., 800 to 1000° C., and 850 to 950° C.

Where it is desired to produce a gem, the method further includes cutting and polishing at least one of the plurality of single crystal diamonds to form a gem. In this instance, and in order to produce a gem of greater than 1 ct, the CVD single crystal diamond has at least one linear dimension no less than 3.5 mm. However, for many technical applications it is often sufficient to use much smaller crystals, for example diamonds with at least one linear dimension no less than 0.5 mm.

The high yield synthesis and post-growth annealing process described above allows a plurality of reproducible gems to be created in a single run, greatly reducing energy costs. This allows diamonds with the required properties to be produced knowing in advance what size and shapes will be needed and having confidence that they will survive the annealing unharmed after minimal processing. Such an uninterrupted process is advantageous over a “stop-start” or layer-by-layer process in, for example, improving equipment utilization efficiency, avoiding the need to prepare the crystals for growth multiple times, and preventing any deleterious effects of interfaces formed between layers grown in successive growth cycles in the material produced. In our preferred embodiment, as detailed by example, growth to full thickness is substantially always performed without interruption.

While this invention has been particularly shown and described with reference to embodiments, it will be understood by those skilled in the art that various changes in form and detail may be made without departing from the scope of the invention as defined by the appended claims.

1. A CVD single crystal diamond having the following characteristics:
a concentration of single substitutional nitrogen atoms, Nₛ⁰, in their neutral charge state as measured by EPR of between 0.25 and 3 ppm;
wherein the CVD single crystal diamond has a total concentration of nitrogen vacancy centres in their neutral and negative charge states (NV⁰ and NV⁻) that is between 0.1 and 0.8 times the Nₛ⁰ concentration.

2. The CVD single crystal diamond according to claim 1, wherein the CVD single crystal diamond has at least one linear dimension no less than 3.5 mm.

3. The CVD single crystal diamond according to claim 1, wherein the CVD single crystal diamond has a hue angle, h_{ab}, selected from any of between −45 and 45°, between −10 and 40°, and between 1° and 40°.

4. The CVD single crystal diamond according to claim 1, wherein the CVD single crystal diamond displays SiV⁻ luminescence, quantitated by the ratio of the total peak area of the SiV⁻ zero-phonon lines to the peak area of the first-order diamond Raman signal in a photoluminescence measurement performed at a temperature of 77 K using an excitation wavelength of 660 nm, selected from any of less than 0.5; less than 0.1; less than 0.05; and less than 0.01.

5. (canceled)

6. The CVD single crystal diamond according to claim 1, wherein a total volume of the single crystal CVD diamond material is selected from any of at least 0.1 mm³, at least 1 mm³, at least 10 mm³, at least 20 mm³, at least 40 mm³, at least 60 mm³, at least 80 mm³ and at least 100 mm³.

7. The CVD single crystal diamond according to claim 1, in the form of a gem, and having a chroma, C*_{ab}, selected from any of 5 to 40, 10 to 35, and 15 to 30.

8. The CVD single crystal diamond according to claim 1, having a measured ensemble NV inhomogeneous dephasing time T2*, as measured by a Ramsey pulse sequence, of greater than 5 μs.

9. The CVD single crystal diamond according to claim 1, in the form of a gem, and having a colour grade, following the Gemological Institute of America (GIA) scale and methodology, that is selected from any of fancy light, fancy, fancy intense, fancy vivid, and fancy deep, in combination with any of pinkish orange, orangey pink, pink, purplish pink, purple pink and pink purple.

10. The CVD single crystal diamond according to claim 1, in the form of a gem, and having a clarity grade, following the Gemological Institute of America (GIA) scale and methodology, that is selected from any of VS₂, VS₁, VVS₂, VVS₁, IF, and FL.

11. The CVD single crystal diamond according to claim 1, further comprising H₃ (NVN⁰) centres.

12. The CVD single crystal diamond according to claim 11, wherein the CVD single crystal diamond displays any of:
a (NV⁰+NV⁻)/H3 ratio of at least 50 in a photoluminescence measurement performed at a temperature of 77 K using an excitation wavelength between 455 and 459 nm, where each of the NV⁰, NV⁻, and H3 defects is quantitated by the peak area ratio of its zero-phonon line to the first-order diamond Raman signal; and
a (NV⁰+NV⁻)/H3 ratio selected from any of at least 100, at least 150, at least 200, at least 300 and at least 400.

13. (canceled)

14. A method of making a plurality of single crystal CVD diamonds according to claim 1, the method comprising:
locating a plurality of single crystal diamond substrates on a substrate carrier within a chemical vapour deposition reactor;
feeding process gases into the reactor, the process gases including a hydrogen-containing gas, a carbon-containing gas, and a nitrogen-containing gas, wherein the relative quantities of the process gases are such as to be stoichiometrically equivalent to a C₂H₂/H₂ ratio between 1% and 4%, and a N₂/C₂H₂ ratio between 30 ppm and 300 ppm;
growing the plurality of single crystal CVD diamonds on the surfaces of at least some of the plurality of single crystal diamond substrates at a temperature of between 750° C. and 1000° C.; and
first annealing at least some of the resultant plurality of single crystal CVD diamonds at a temperature of between 1500° C. and 1800° C.;
irradiating the plurality of single crystal CVD diamonds to form vacancies in the diamond crystal lattice; and
second annealing the resultant plurality of single crystal CVD diamonds at a temperature of between 700° C. and 1100° C.

15. The method according to claim 14, wherein the relative quantities of the process gases are such as to be stoichiometrically equivalent to a N₂/C₂H₂ ratio selected from any of between 50 and 200 ppm, between 60 and 180 ppm, and between 70 and 150 ppm.

16. The method according to claim 14, wherein the relative quantities of the process gases are such as to be stoichiometrically equivalent to a C₂H₂/H₂ ratio selected from any of 1 to 3%, 1.5 to 2.5%, and 1.5 to 2%.

17. The method according to claim 14, wherein the first annealing is performed at a temperature of between 1550° C. and 1750° C.

18. The method according to claim 14, wherein the first annealing is performed under diamond-stabilising pressure.

19. The method according to claim 14, wherein the irradiation is performed using electron irradiation at between 1 and 10 MeV.

20. The method according to claim 14, wherein the second annealing comprises annealing in a temperature range selected from any of 700 to 1000° C., 800 to 1000° C., and 850 to 950° C.

21. (canceled)

22. (canceled)

23. The method according to claim 14, wherein the step of growing the plurality of single crystal CVD diamonds provides a volumetric growth rate for single-crystal diamond material that is selected from any of at least 10 mm³/h, at least 20 mm³/h, at least 30 mm³/h, at least 40 mm³/h, and at least 50 mm³/h.

24. (canceled)

25. A device comprising the CVD single crystal diamond according to claim 1, the device being selected from any of an imaging device, a sensing device, a magnetometer; a spin resonance device, a quantum information processing device, and a gyroscope device.
